(19) United States
(12) Patent Application Publication
(10) Pub. No.: US 2011/0216491 A1
(43) Pub. Date: Sep. 8, 2011

(54) COMPUTER MAIN BODY

(76) Inventors: Ming-Yi Lian, TAIPEI CITY (TW); Shih-Jen Liao, TAIPEI CITY (TW)

(21) Appl. No.: 12/960,531

(22) Filed: Dec. 5, 2010

(30) Foreign Application Priority Data
Mar. 8, 2010 (TW) 099204046

(51) Int. Cl. G06F 1/16; H05K 5/02

(52) U.S. Cl. 361/679.4

(57) ABSTRACT

A computer main body includes a casing and an input/output ports integrated device. The casing has a top surface, and the top surface has an opening. The input/output ports integrated device is disposed in the casing, and the input/output ports integrated device springs out of the top surface via the opening along a normal direction of the top surface or is contained in the casing. The input/output ports integrated device includes a plurality of input/output ports disposed at side surfaces of the input/output ports integrated device.

### CROSS-REFERENCE TO RELATED APPLICATIONS

This Non-provisional application claims priority under 35 U.S.C. §119(a) on Patent Application No(s). 099204046 filed in Taiwan, Republic of China on Mar. 8, 2010, the entire contents of which are hereby incorporated by reference.

### BACKGROUND OF THE INVENTION

1. Field of the Invention

This invention relates to a computer main body and, more particularly, to a computer main body including a plurality of input/output ports and capable of being conveniently used.

2. Description of the Related Art

A computer main body usually includes a plurality of input/output ports, such as a USB port, a mouse connecting port, and a keyboard connecting port and so on, for inputting/outputting data. In early days, the input/output ports are disposed at a back plate of the computer main body. Therefore, when a user uses the input/output ports every time, he or she needs to circle a plug of an expansion device to the back plate of the computer main body for plugging, which causes great inconvenience for the user.

### BRIEF SUMMARY OF THE INVENTION

This invention provides a computer main body including a plurality of input/output ports and capable of being conveniently used.

This invention provides a computer main body including a casing and an input/output ports integrated device. The casing has a top surface, and the top surface has an opening. The input/output ports integrated device is disposed in the casing, and the input/output ports integrated device springs out of the top surface via the opening along a normal direction of the top surface or is contained in the casing. The input/output ports integrated device includes a plurality of input/output ports disposed at side surfaces of the input/output ports integrated device.

In one embodiment of the invention, the casing may further include a containing groove for containing the input/output ports integrated device. The opening of the top surface of the casing communicates with the containing groove. The input/output ports integrated device springs out of the top surface via the opening or is contained in the containing groove.

In one embodiment of the invention, the computer main body may further include an elastic device disposed between the input/output ports integrated device and a bottom of the containing groove to allow the input/output ports integrated device to spring out of the top surface.

In one embodiment of the invention, the elastic device may further include a plurality of elastic elements. One end of each elastic element is connected with the input/output ports integrated device, and the other end of each elastic element is connected with the bottom of the containing groove.

In one embodiment of the invention, the elastic device may further include a plurality of protrudent columns disposed at the bottom of the containing groove. The other end of each elastic element is sleeved on the respective protrudent column.

In one embodiment of the invention, the elastic device may further include a plurality of sleeves, and each sleeve may be sleeved on the end of the respective elastic element.

In one embodiment of the invention, each sleeve may be disposed at a bottom surface of the input/output ports integrated device to correspond to the respective protrudent column.

In one embodiment of the invention, the computer main body may further include a locking assembly disposed between the input/output ports integrated device and the bottom of the containing groove to ensure that the input/output ports integrated device is contained in the casing.

In one embodiment of the invention, the locking assembly may include a hook and a locking groove. The hook is disposed at a bottom surface of the input/output ports integrated device, and the locking groove is disposed at the bottom of the containing groove to correspond to the hook. The hook is separably locked to the locking groove to allow the input/output ports integrated device to be contained in the containing groove or to spring out of the top surface via the opening.

In one embodiment of the invention, the input/output ports integrated device may include an upper cover, a bottom plate, and a plurality of side plates. The side plates are erected between a bottom surface of the upper cover and a top surface of the bottom plate and form a containing space with the upper cover and bottom plate. The input/output ports are disposed in the containing space and are exposed from the side plates.

In one embodiment of the invention, an area of the bottom plate may be greater than that of the opening of the casing.

In one embodiment of the invention, an area of the upper cover may be equal to or smaller than that of the opening of the casing.

According to the computer main body in the invention, a plurality of input/output ports are integrated into one input/output ports integrated device, and the input/output ports integrated device can spring out of the top surface of the casing of the computer main body, such that a user can conveniently plug an expansion device into the input/output ports integrated device which springs out of the top surface of the computer main body. Compared with the prior art in which ports are disposed at the back plate, the user can connect an expansion device without moving the position of the computer main body, which is convenient in use via the computer main body provided in the invention.

These and other features, aspects, and advantages of the present invention will become better understood with regard to the following description, appended claims, and accompanying drawings.

### BRIEF DESCRIPTION OF THE DRAWINGS

FIG. 1 and FIG. 2 are schematic diagrams showing two different states that an input/output ports integrated device of a computer main body springs out of a casing and is contained in the casing according to one embodiment of this invention, respectively;

FIG. 3 is a partial sectional diagram of FIG. 1;

FIG. 4 is a schematic diagram showing a bottom of a containing groove;

FIG. 5 is a schematic diagram showing a bottom surface of an input/output ports integrated device;

FIG. 6 is a schematic diagram showing a locking assembly; and

FIG. 7 is a schematic diagram showing an input/output ports integrated device and a containing groove.

### DETAILED DESCRIPTION OF THE INVENTION

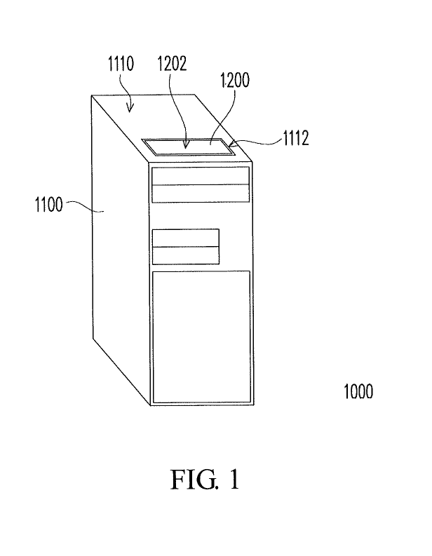

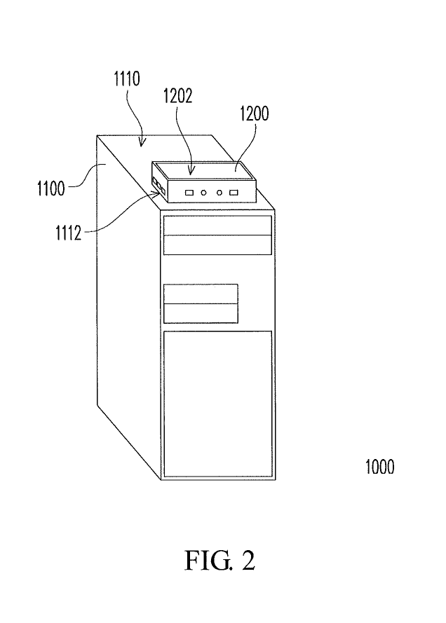

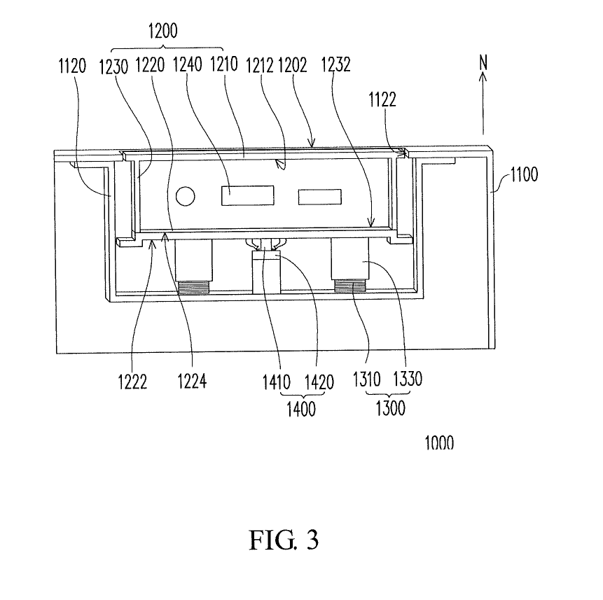

FIG. 1 and FIG. 2 are schematic diagrams showing two different states that an input/output ports integrated device of a computer main body springs out of a casing and is contained in the casing according to one embodiment of this invention, respectively. FIG. 3 is a partial sectional diagram of FIG. 1. Please refer to FIG. 1, FIG. 2, and FIG. 3 together. In the embodiment, a computer main body 1000 includes a casing 1100 and an input/output ports integrated device 1200. The casing 1100 has a top surface 1110, and the top surface 1110 has an opening 1112. The input/output ports integrated device 1200 springs out of the top surface 1110 via the opening 1112 along a normal direction of the top surface 1110 or is contained in the casing 1100, and the input/output ports integrated device 1200 includes a plurality of input/output ports 1240 disposed at side surfaces of the input/output ports integrated device 1200.

In detail, the casing 1100 includes a containing groove 1120 for containing the input/output ports integrated device 1200, and the opening 1112 of the top surface 1110 of the casing 1100 communicates with the containing groove 1120. In addition, the computer main body 1000 further includes an elastic device 1300 disposed between the input/output ports integrated device 1200 and a bottom of the containing groove 1120. The elastic device 1300 includes a plurality of elastic elements 1310. The elastic elements 1310 may be compression springs. One end of each elastic element 1300 is connected with the input/output ports integrated device 1200, and the other end is connected with the bottom of the containing groove 1120.

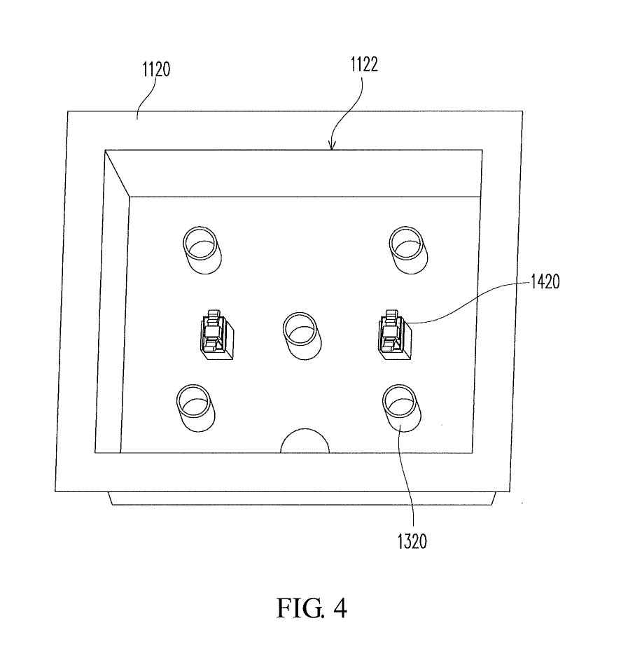

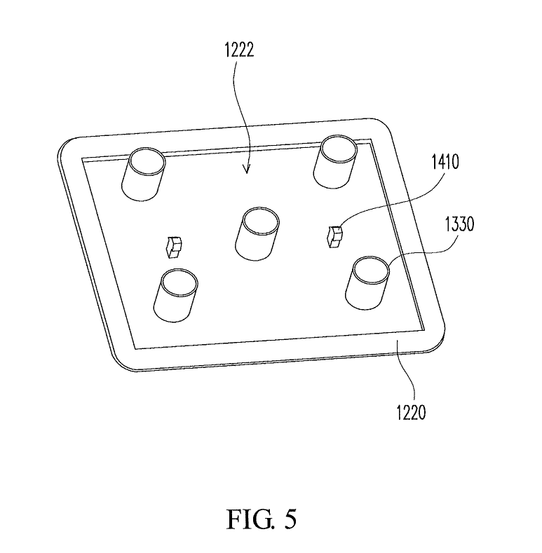

FIG. 4 is a schematic diagram showing the bottom of the containing groove 1120. FIG. 5 is a schematic diagram showing a bottom surface of the input/output ports integrated device 1200. In FIG. 4 and FIG. 5, the elastic device 1300 further includes a plurality of protrudent columns 1320 disposed at the bottom of the containing groove 1120, and the other end of each elastic element 1310 is sleeved on the respective protrudent column 1320 for limiting a two-dimensional movement of the other end of the respective elastic element 1310 relative to the bottom of the containing groove 1120. In addition, the elastic device 1300 further includes a plurality of sleeves 1330, and each sleeve 1330 is sleeved the end of the respective elastic element 1310 connected with the input/output ports integrated device 1200 for limiting a a two-dimensional movement of the end of the respective elastic element 1310 relative to the input/output ports integrated device 1200. The sleeves 1330 are disposed at a bottom surface 1222 of the input/output ports integrated device 1200 to correspond to the protrudent columns 1320. The two ends of each elastic element 1310 are sleeved outside the respective protrudent column 1320 and inside the respective sleeve 1330, respectively, thereby ensuring that the elastic elements 1310 are compressed or provide elastic restoring force only along the normal direction N.

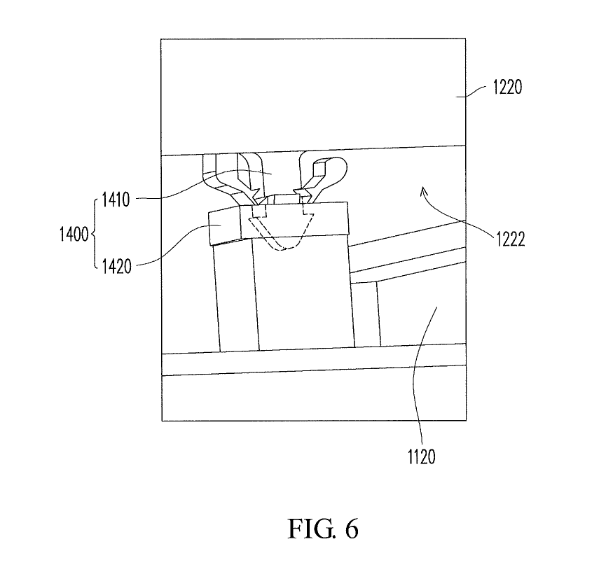

FIG. 6 is a schematic diagram showing a locking assembly. Please refer to FIG. 3, FIG. 4, and FIG. 6 together. The computer main body 1000 further includes a locking assembly 1400 disposed between the input/output ports integrated device 1200 and the bottom of the containing groove 1120. The locking assembly 1400 includes a hook 1410 and a locking groove 1420. The hook 1410 is disposed at the bottom surface 1222 of the input/output ports integrated device 1200. The locking groove 1420 is disposed at the bottom of the containing groove 1120 to correspond to the hook 1410. When the hook 1410 and the locking groove 1420 of the locking assembly 1400 are locked together, the input/output ports integrated device 1200 can be contained in the containing groove 1120 to prevent the input/output ports integrated device 1200 from springing out of the top surface 1110 via the opening 1112. In addition, the hook 1410 is separably locked to the locking groove 1420. When the hook 1410 and the locking groove 1420 of the locking assembly 1400 are separated from each other, the input/output ports integrated device 1200 can spring out of the top surface 1110 via the opening 1112.

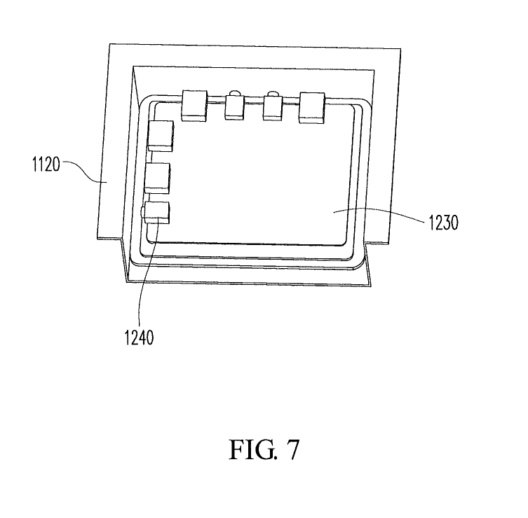

FIG. 7 is a schematic diagram showing the input/output ports integrated device and the containing groove. To clearly show the input/output ports 1240, an upper cover 1210 and side plates 1230 are omitted. Please refer to FIG. 3 and FIG. 7 together. The input/output ports integrated device 1200 includes an upper cover 1210, a bottom plate 1220, and a plurality of side plates 1230. The side plates 1230 are erected between a bottom surface 1212 of the upper cover 1210 and a top surface 1224 of the bottom plate 1220 and form a containing space with the upper cover 1210 and the bottom plate 1220. The input/output ports 1240 are disposed in the containing space and are exposed from the side plates 1230. In the embodiment, an area of the bottom plate 1220 is greater than that of the opening 1112 of the casing 1100, and an area of the upper cover 1210 is equal to or smaller than that of the opening 1112 of the casing 1100.

Please refer FIG. 1, FIG. 3, and FIG. 6 together. Generally in a stored state, the input/output ports integrated device 1200 is contained in the containing groove 1120. When the hook 1410 and the locking groove 1420 of the locking assembly 1400 are locked to each other, the input/output ports integrated device 1200 is prevented from springing out of the top surface 1110 via the opening 1112, and the elastic elements 1310 are pressed by the bottom plate 1220 of the input/output ports integrated device 1200 and the bottom of the containing groove 1120 to store elastic restoring force. In addition, for appearance integrity and aesthetics of the computer main body 1000, the top surface 1202 of the input/output ports integrated device 1200 is usually level with the top surface 1110 of the casing 1100.

Then please refer to FIG. 2, FIG. 3, and FIG. 6. A user presses the top surface 1202 of the input/output ports integrated device 1200 when the user wants to use the input/output port 1240 of the input/output ports integrated device 1200. The input/output ports integrated device 1200 suffers the force to move along a direction opposite to the normal direction N for releasing the hook 1410 from the locking groove 1420, and then the elastic restoring force of the elastic elements 1310 allows the input/output ports integrated device 1200 to spring out of the top surface 1110 of the casing 1100 along the normal direction N. At that moment, the user can conveniently insert a plug of an input/output device (not shown) into the input/output port 1240 for use.

The two ends of each elastic element 1310 are sleeved inside the respective sleeve 1330 and outside the respective protrudent column 1320, respectively, thus to limit a release direction of the elastic restoring force of the elastic element 1310. In addition, the area of the upper cover 1210 of the input/output ports integrated device 1200 is equal to or smaller than that of the opening 1112 of the casing 1100, such that the upper cover 1210 of the input/output ports integrated device 1200 and the casing 1100 can be integrated into a whole on appearance. The area of the bottom plate 1220 of the input/output ports integrated device 1200 is greater than that of the opening 1112 of the casing 1100. Therefore, when the input/output ports integrated device 1200 springs out of the casing 1100 along the normal direction N, the edges of the bottom plate 1220 may be limited by the edges of the opening 1112, thus to limit the movement of the input/output ports integrated device 1200 and to prevent the input/output ports integrated device 1200 from springing out of the casing 1100 wholly.

The users just need to press the input/output ports integrated device 1200 without other additional steps, such that the hook 1410 and the locking groove 1420 can be locked to each other or released from each other, further to allow the input/output ports integrated device 1200 to be in a storage state or in a using state. In other words, the computer main body in the embodiment can be conveniently operated by the users.

To sum up, according to the computer main body in the embodiment, the users can be free from moving the computer main body or inserting the plug of the expansion device into the input/output ports of the computer main body via circling back to the computer main body. In addition, via the elastic device, the input/output ports integrated device can move along the normal direction of the top surface of the casing upward or downward to spring out of the casing or to be contained in the casing, thus to overcome difficulties in design further to save space, thereby allowing the input/output ports to be disposed at the periphery of the input/output ports integrated device to improve expansion of the ports. In addition, via the locking structure, the users can change the state of the input/output ports integrated device just by simple pressing mode. Therefore, the computer main body in the embodiment of the invention can be operated simply and conveniently.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A computer main body comprising:
a casing having a top surface, the top surface having an opening; and
an input/output ports integrated device disposed in the casing, wherein the input/output ports integrated device springs out of the top surface via the opening along a normal direction of the top surface or is contained in the casing, and the input/output ports integrated device includes a plurality of input/output ports disposed at side surfaces of the input/output ports integrated device.

2. The computer main body according to claim 1, wherein the casing further comprises a containing groove for containing the input/output ports integrated device, the opening of the top surface of the casing communicates with the containing groove, and the input/output ports integrated device springs out of the top surface via the opening or is contained in the containing groove.

3. The computer main body according to claim 2, further comprising an elastic device disposed between the input/output ports integrated device and a bottom of the containing groove to allow the input/output ports integrated device to spring out of the top surface.

4. The computer main body according to claim 3, wherein the elastic device comprises a plurality of elastic elements, one end of each elastic element is connected with the input/output ports integrated device, and the other end of each elastic element is connected with the bottom of the containing groove.

5. The computer main body according to claim 4, wherein the elastic device further comprises a plurality of protrudent columns disposed at the bottom of the containing groove, and the other end of each elastic element is sleeved on the respective protrudent column.

6. The computer main body according to claim 5, wherein the elastic device further comprises a plurality of sleeves and each sleeve is sleeved on the end of the respective elastic element.

7. The computer main body according to claim 6, wherein each sleeve is disposed at a bottom surface of the input/output ports integrated device to correspond to the respective protrudent column.

8. The computer main body according to claim 2, further comprising a locking assembly disposed between the input/output ports integrated device and the bottom of the containing groove to ensure that the input/output ports integrated device is contained in the casing.

9. The computer main body according to claim 8, wherein the locking assembly comprises a hook and a locking groove, the hook is disposed at a bottom surface of the input/output ports integrated device, the locking groove is disposed at the bottom of the containing groove to correspond to the hook, and the hook is separably locked to the locking groove to allow the input/output ports integrated device to be contained in the containing groove or to spring out of the top surface via the opening.

10. The computer main body according to claim 1, wherein the input/output ports integrated device comprises:
an upper cover;
a bottom plate; and
a plurality of side plates erected between a bottom surface of the upper cover and a top surface of the bottom plate and forming a containing space with the upper cover and the bottom plate, the input/output ports disposed in the containing space and exposed from the side plates.

11. The computer main body according to claim 10, wherein an area of the bottom plate is greater than that of the opening of the casing.

12. The computer main body according to claim 10, wherein an area of the upper cover is equal to or smaller than that of the opening of the casing.
